(19) United States
(12) Patent Application Publication
(10) Pub. No.: US 2017/0178875 A1
(43) Pub. Date: Jun. 22, 2017

(54) INSULATOR TARGET

(71) Applicant: ULVAC, INC., Kanagawa (JP)

(72) Inventors: Shinji Kohari, Kanagawa (JP); Hiroki Yamamoto, Kanagawa (JP); Yoji Taguchi, Kanagawa (JP); Takahiro Nanba, Kanagawa (JP)

(73) Assignee: ULVAC, INC., Kanagawa (JP)

(21) Appl. No.: 15/324,430

(22) PCT Filed: Jun. 2, 2015
(86) PCT No.: PCT/JP2015/002792

§ 371 Date: Jan. 6, 2017

(30) Foreign Application Priority Data
Jul. 9, 2014 (JP) 2014-141680

(51) Int. Cl. H01J 37/34

(52) U.S. Cl. CPC H01J 37/3417; H01J 37/3426; H01J 37/345

(57) ABSTRACT

There is provided an insulator target which, when mounted on a sputtering apparatus and supplied with AC power, is capable of preventing the discharging from occurring in a clearance between a shield and the target. The insulator target for the sputtering apparatus according to this invention, around which is disposed a shield at the time of assembling the insulator target on the sputtering apparatus, is made up of: a plate-shaped target material to be enclosed by the shield; and, suppose that one surface of the target material is defined as a sputtering surface to be subjected to sputtering, an annular supporting material coupled to an outer peripheral portion of the opposite surface of the target material. The supporting material has an extended portion which is extended outward from a peripheral surface of the target material and which keeps a predetermined clearance to the shield.

### TECHNICAL FIELD

The present invention relates to an insulator target adapted for use in a sputtering apparatus.

### BACKGROUND ART

Insulating films such as aluminum oxide film, magnesium oxide film and the like are used, e.g., as tunnel barriers of magnetic random access memories (MRAM) and, in order to deposit insulating films with good mass productivity, a sputtering apparatus is employed. In this apparatus, a sputtering gas is introduced into a vacuum chamber in which a substrate and an insulator target (hereinafter also referred to as a “target”) are disposed so as to lie opposite to each other. Along with the operation, AC power is supplied to the target to thereby form plasma in a space between the substrate and the target. The sputtering surface of the target is thus sputtered so that the splashed sputter particles get adhered to, and deposited on, the substrate, thereby forming an insulating film.

Here, in order to prevent the parts (e.g., backing plate) other than the target from getting sputtered by the plasma sneaking up to the side surfaces of the target, there is known in Patent Document 1 an art in which a shield is disposed around the target at the time of assembling the target to the sputtering apparatus. According to this known art, the peripheral portion of the target is made thinner in thickness and, instead, a shield is disposed on the thinned peripheral portion while keeping a predetermined distance from one another.

However, when AC power is supplied to the thinned target whose peripheral portion has been thinned as in the above-mentioned known example, it has been found that discharging occurs in the clearance between the target and the shield. This phenomenon seems to be due to the fact that, during sputtering, the entire insulator target fails to attain the same electric potential but, as compared with the impedance in the central portion of the target, the impedance in the peripheral portion of the thinned target becomes lower.

### PRIOR ART DOCUMENT

### Patent Document

Patent document 1: JP-A-2001-64773

### SUMMARY OF THE INVENTION

### Problems to be Solved by the Invention

In view of the above points, this invention has a problem of providing an insulator target in which, when the insulator target is mounted on the sputtering apparatus and AC power is supplied thereto, electric discharging can be prevented from occurring in a clearance between the shield and the target.

### Means for Solving the Problems

In order to solve the above problems, this invention is an insulator target adapted for use in a sputtering apparatus wherein, at a time of mounting the insulator target on the sputtering apparatus, a shield is disposed around a periphery of the insulator target. The insulator target comprises: a plate-shaped target material enclosed by the shield; and suppose that one surface of the target material is defined as a sputtering surface to be subjected to sputtering, an annular supporting material coupled to an outer peripheral portion of an opposite surface of the target material. The supporting material has an extended portion which is extended outward from a peripheral surface of the target material and which keeps a predetermined clearance to the shield. The supporting material is arranged to have an impedance equal to, or above, an impedance of the target material when the sputtering surface is subjected to sputtering by supplying AC power to the insulator target. This invention shall be understood to include, not only an embodiment in which a separately formed target material and a supporting material are coupled, but also an embodiment in which the target material and the supporting material are integrally formed.

According to this invention, unlike the conventional example in which the peripheral portion of the target is made thinner so as to dispose therein the shield, the target of this invention comprises the target material and the annular supporting material. When the sputtering surface is subjected to sputtering in a state in which the shield is disposed at a predetermined clearance from the extended portion of the supporting material, the supporting material is arranged to have an impedance equal to, or above, the impedance of the target material. Therefore, the occurrence of electric discharging between the target and the shield can be prevented. Constituent parts other than the target can thus be prevented from getting sputtered.

In this invention, by arranging that the target material and the supporting material are made of the same material, and that the supporting material has a thickness equal to, or above, the thickness of the target material, the impedance of the supporting material can be made, at the time of sputtering, to be equal to, or above, the impedance of the target material.

In this invention, the target material and the supporting material may be made of different materials. In this case, if the supporting material is made of a material having a lower dielectric constant than that of the target material, the supporting material can be made thinner than the plate thickness of the target material. Therefore, the insulator target can be manufactured with good workability. Further, as compared with an example in which the target material and the supporting material are made of the same material, the manufacturing cost of the insulator target can be reduced.

### BRIEF DESCRIPTION OF THE DRAWINGS

FIG. 1 is a schematic sectional view of a sputtering apparatus having mounted thereon an insulator target.

FIG. 2 is an enlarged sectional view of the insulator target.

FIGS. 3(a) and 3(b) are sectional views respectively showing other embodiments of the insulator target.

### MODES FOR CARRYING OUT THE INVENTION

With reference to the drawings a description will now be made of an insulator target according to an embodiment of this invention, taking as an example to be mounted on a sputtering apparatus. In each of the drawings the same reference numerals are assigned to the elements that are common to each other, thereby omitting duplicating explanations.

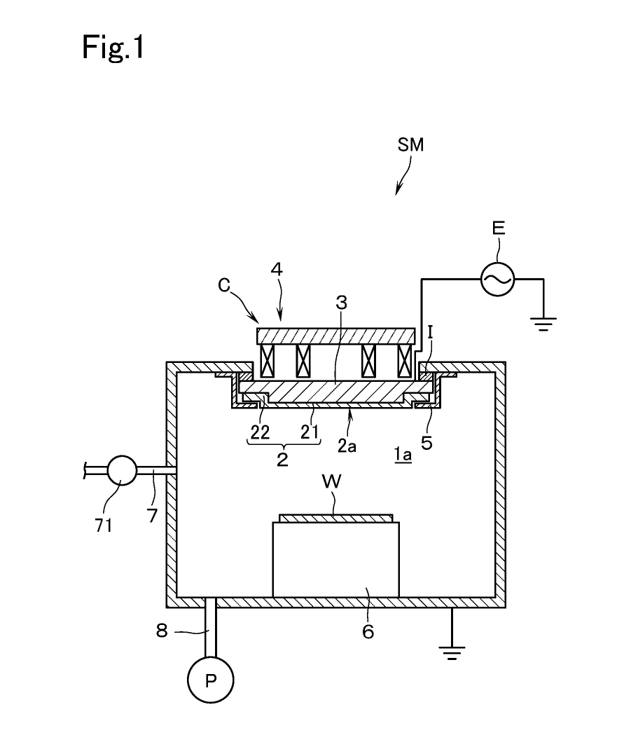

With reference to FIG. 1, the reference mark SM denotes a magnetron type of sputtering apparatus. This sputtering apparatus SM is provided with a vacuum chamber 1 which defines a vacuum processing chamber 1a. On a ceiling portion of the vacuum chamber 1 there is mounted a cathode unit C. In the following, explanation will be made on condition that, in FIG. 1, the direction that looks toward the ceiling portion of the vacuum chamber 1 is defined as “up” and that the direction that looks toward the bottom side of the vacuum chamber is defined as “lower.” The cathode unit C is made up of: an insulator target 2; a backing plate 3 disposed on the insulator target 2; and a magnet unit 4 which is disposed above the backing plate 3.

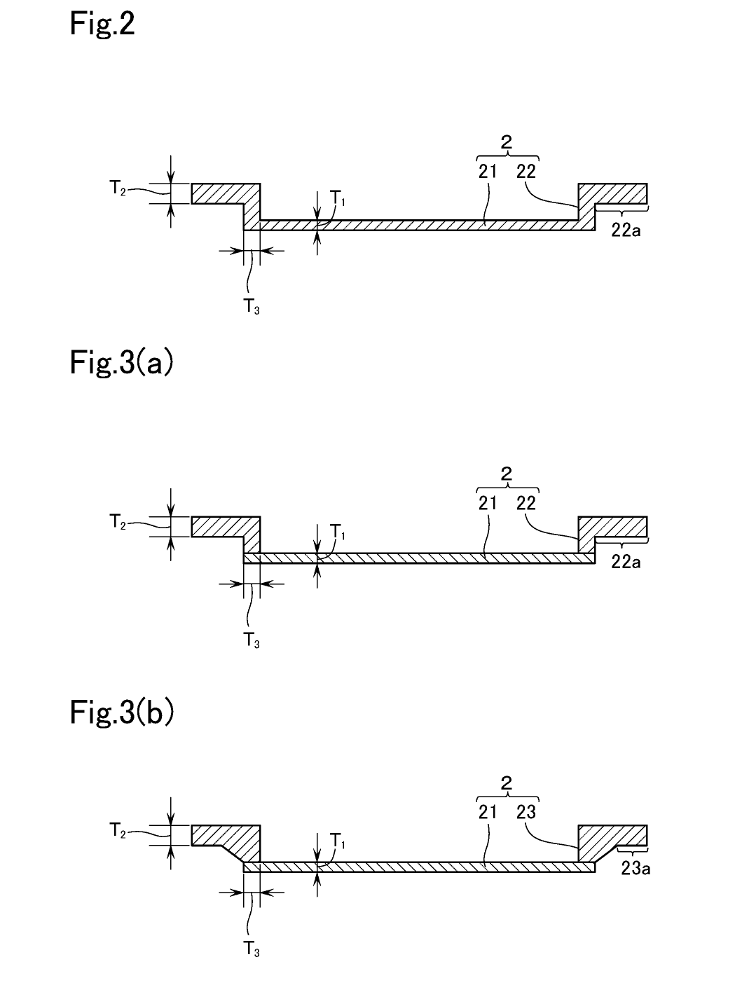

With reference also to FIG. 2, the insulator target 2 comprises: a target material 21 which is made of an insulator material and is formed into an annular plate shape, as seen in plan view, according to a known method depending on the contour of a substrate W; and an annular supporting material 22 which is coupled, provided that the lower surface of the target material 21 is defined as a sputtering surface (surface to be subjected to sputtering) 2a, to an outer peripheral portion on the upper surface that is opposite to the sputtering surface 2a. The target material 21 and the supporting material 22 are integrally formed of the same material. The supporting material 22 is arranged to have thicknesses T₂, T₃ that are equal to, or above, the plate thickness T₁ of the target material 21. In this case, the plate thickness T₁ may be set to a range of 1 mm to 15 mm, and that plate thickness T₂ of the supporting material 22 which extends in a direction perpendicular to the sputtering surface 2a, and the plate thickness T₃ of an extended portion 22a, which will be described hereinafter, can be set to a range of 2 mm to 20 mm. The supporting material 22 has the extended portion 22a that extends from the peripheral surface of the target material 21 outward. A metal shield 5 is disposed while keeping a predetermined clearance (e.g., 0.5 mm to 5 mm) to the extended portion 22a so that sputtering does not occur on surfaces other than the sputtering surface 2a. The shield 5 may be grounded or floating and one that has the known construction may be used. Therefore, detailed explanation thereabout will be omitted here. Further, by making the sputtering surface 2a of the target material 21 flush (on the same level) with the lower surface of the shield 5, the shield 5 is thus arranged to be hardly deposited with a film.

The backing plate 3 is coupled to the upper surface (i.e., the surface that is opposite to the sputtering surface 2a) of the target 2 so that the target 2 can be cooled during film deposition by sputtering. The backing plate 3 is attached at the peripheral portion on the upper surface of the backing plate 3 to an inner surface of the upper wall of the vacuum chamber 1 via an insulating body I. The target 2 has connected thereto an output of AC power supply E such as RF power supply, etc. so that AC power can be supplied to the target 2 during film deposition. The magnet unit 4 has a known construction in that a magnetic field is generated in a space below the sputtering surface 2a of the target 2 and that the electrons, etc. ionized below the sputtering surface 2a at the time of sputtering are captured to efficiently ionize the sputtering particles scattered from the target 2. Detailed explanation will therefore be omitted here.

At the bottom portion of the vacuum chamber 1 there is disposed a stage 6 in a manner to lie opposite to the sputtering surface 2a of the target 2. The substrate W is held in position with the film-deposition surface lying upward. In this case, the clearance between the target 2 and the substrate W is set to a range of 45 mm to 100 mm in view of the productivity and the number of scattering, etc. The side wall of the vacuum chamber 1 has connected thererto a gas pipe 7 for introducing a sputtering gas which is a rare gas such as argon, etc. The gas pipe 7 has interposed therein a master flow controller 71, and is connected to a gas source (not illustrated). According to this arrangement, the flow-controlled sputtering gas can be introduced into the vacuum processing chamber 1a that has been evacuated at a predetermined evacuation speed by evacuating means P which is described in detail hereinafter. It is thus so arranged that, during film deposition, the pressure (total pressure) in the vacuum processing chamber 1a can be maintained approximately constant. The bottom portion of the vacuum chamber 1 has connected thereto an exhaust pipe 8 which is communicated with the evacuating means P made up of a turbo molecular pump, rotary pump, etc. Although not particularly illustrated, the above-mentioned sputtering apparatus SM has a known control means provided with a microcomputer, sequencer, etc. By means of the control means it is so arranged that an overall control can be made over the operation of the power supply E, operation of the mass-flow controller 71, operation of the evacuating means P, etc. Description will be made hereinafter, on condition that the insulator target 2 is a magnesium oxide target, of a method of depositing a magnesium oxide film on the surface of the substrate W using a sputtering apparatus SM having assembled therein the above-mentioned target 2.

After setting in position the substrate W on the stage 6 inside the vacuum chamber 1 in which the target 2 has been assembled, the evacuating means P is operated to evacuate the vacuum processing chamber 1a down to a predetermined vacuum (e.g., 1×10⁻⁵ Pa). Once the vacuum processing chamber 1a has reached a predetermined pressure, the mass flow controller 71 is controlled to introduce argon gas at a predetermined flow rate (at this time the pressure inside the vacuum processing chamber 1a attains a range of 0.01 Pa to 30 Pa). In parallel therewith, AC power having a negative electric potential is supplied from the sputtering power source E to the target 2 so as to form plasma inside the vacuum chamber 1. As a result, the sputtering surface 2a of the target material 21 gets sputtered, and the scattered sputtering particles will get adhered to the surface of the substrate W and deposited thereon, whereby a magnesium oxide film is formed.

According to this embodiment, the target 2 is made up of the target material 21 and the supporting material 22, both being of the same material. The shield 5 is disposed in a manner to keep a predetermined clearance from the extended portion 22a of the supporting material 22. The supporting material 22 is arranged to have the plate thicknesses T₂, T₃ that are equal to, or above, the plate thickness T₁ of the target material 21. Therefore, unlike the above-mentioned conventional example in which the peripheral portion of the target is made thinner in plate thickness, according to this invention, when AC power is supplied to the insulator target 2 so that the sputtering surface 2a gets sputtered, the supporting material 22 will have an impedance that is equal to, or above, the impedance of the target material 21. According to this arrangement, the occurrence of discharging between the target 2 and the shield 5 can be prevented. In other words, the plasma can be prevented from sneaking up to the side surfaces of the target 2, whereby the parts other than the target can be prevented from getting sputtered.

A description has so far been made of an embodiment of this invention, but this invention shall not be limited to the above. In the above-mentioned embodiment, the target material 21 and the supporting material 22 are integrally formed, but they may be separately formed and then coupled together. In this case, the workability of the target 2 can be improved. Further, as shown in FIG. 3(a), the target material 21 and the supporting material 22 may be formed of different materials. In this case, by forming the supporting material 22 in a material (for example, quartz, glass epoxy, etc.) that is lower in dielectric constant than that of the target material 22, the plate thicknesses T₂, T₃ of the supporting material 22 can be formed thinner than the plate thickness T₁ of the target material 21. The workability can still further be improved to advantage. Still furthermore, because the supporting material 22 is not subjected to sputtering, no contamination will occur. Further, the shape of the supporting material is not particularly limited. As shown in FIG. 3(b), those portions other than the extended portion 23a of the supporting material 23, i.e., the portions to be coupled to the target material 21, may be formed into a tapered shape. By the way, magnesium oxide was used as an example in explaining the material of the target material 21, but without being limited thereto, other insulators such as aluminum oxide, etc. may be appropriately selected depending on the film to be deposited.

Next, in order to confirm the above-mentioned effect, the following experiments were conducted using the above-mentioned sputtering apparatus SM. In these experiments, as the substrate W a Si substrate of 300 mm in diameter was used. After setting the substrate W in position on the stage 6 inside the vacuum chamber 1 in which the target 2 of magnesium oxide is assembled, magnesium oxide film was formed on the surface of the substrate W by sputtering method. The conditions at this time were as follows, namely, the plate thickness T₁ of the target material 21 was 3 mm, the plate thickness T₂ of the supporting material 22 was 4 mm, and the plate thickness T₃ was made to be 4 mm. The flow amount of argon gas was set to be 20 sccm (the pressure inside the vacuum processing chamber 1a at this time was about 0.4 Pa), and the power supply to the target 2 was set to be 13.56 MHz, 0.5 kW. The number of particles after film deposition was measured and the results are shown in Table 1 as this invention. According to this, the number of particles below 0.09 μm was stable at a level below 10 pieces. From these results, it was found that the discharging between the target 2 and the shield 5 was prevented from occurring and that the parts other than the target were found free from sputtering.

TABLE 1

| | This invention | Conventional Example |
|---|---|---|
| Number of particles | 0 to 10 pieces | 200 to 600 pieces |
| (below 0.09 μm) | | |

On the other hand, except for the point that there was used a target that was made thinner in the peripheral portion of the target as in the above-mentioned conventional example, film was deposited by sputtering on the same conditions as those in the above-mentioned conventional examples. The result of similarly measuring the number of particles is shown as conventional example in Table 1. According to this, the number of particles was as many as above 100 pieces (200 pieces to 600 pieces). It was thus confirmed that discharging occurred between the target and the shield.

It is to be noted that the size of the above-mentioned substrate W is not limited to the above-mentioned example of 300 mm in diameter, but substrates of, for example, 150 mm to 300 mm in diameter may be used. In addition, the target diameter is not particularly limited, but the diameter may be appropriately set, e.g., in the range of 120 mm to 400 mm in diameter, taking into consideration the deposition characteristics and production efficiency.

### DESCRIPTION OF REFERENCE MARKS

SM sputtering apparatus
2 insulator target
2a sputtering surface (surface to be subjected to sputtering)
21 target material
22 supporting material
22a extended portion
5 shield
T₁ plate thickness of target material
T₂, T₃ plate thickness of supporting material

1. An insulator target adapted for use in a sputtering apparatus wherein, at a time of mounting the insulator target on the sputtering apparatus, a shield is disposed around a periphery of the insulator target, the insulator target comprising:
a plate-shaped target material enclosed by the shield; and
suppose that one surface of the target material is defined as a sputtering surface to be subjected to sputtering, an annular supporting material coupled to an outer peripheral portion of an opposite surface of the target material, the supporting material having an extended portion which is extended outward from a peripheral surface of the target material and which keeps a predetermined clearance to the shield,
wherein the supporting material is arranged to have an impedance equal to, or above, an impedance of the target material when the sputtering surface is subjected to sputtering by supplying AC power to the insulator target.

2. The insulator target according to claim 1, wherein the target material and the supporting material are made of a same material, and wherein the supporting material has a thickness equal to, or above, the thickness of the target material.

3. The insulator target according to claim 1, wherein the target material and the supporting material are made of different materials.
